(19) United States
(12) Patent Application Publication
(10) Pub. No.: US 2009/0241988 A1
(43) Pub. Date: Oct. 1, 2009

(54) PHOTORESIST AND ANTIREFLECTIVE LAYER REMOVAL SOLUTION AND METHOD THEREOF

(75) Inventors: Vijayakumar S. RAMACHANDRARAO, Portland, OR (US); Melanie S. Reyes, Albuquerque, NM (US); Shan Clark, Forest Grove, OR (US); John O'Sullivan, Trim (IE)

Correspondence Address: PEARL COHEN ZEDEK LATZER, LLP, 1500 BROADWAY, 12TH FLOOR, NEW YORK, NY, 10036, US

(73) Assignee: Intel Corporation

(21) Appl. No.: 12/058,797

(22) Filed: Mar. 31, 2008

(51) Int. Cl. G03F 7/42; B08B 7/00

(52) U.S. Cl. 134/1.3; 510/176

(57) ABSTRACT

An aqueous solution composition may include an organic base hydroxide, potassium hydroxide, a compound selected from the group of compounds consisting of 2-mercaptobenzimidazole, 1-Phenyl-1H-tetrazole-5-thiol and 2-MerCaptoBenzoThiazole, hydrogen peroxide and deionized water. A method for removing photoresist and anti-reflective coating from a wafer using such a solution is also disclosed.

### FIELD OF THE INVENTION

The present invention relates to the manufacture of semiconductors. More specifically it relates to removal of etched photoresist and silicon-based and/or an organic anti-reflective coating with alkaline solutions, typically in backend of the production line of semiconductors.

### BACKGROUND OF THE INVENTION

In a typical photolithography process, a photosensitive material is spun-on to cover a wafer, and light is irradiated through a photomask onto the photosensitive layer covering the wafer and the wafer undergoes development to produce a predetermined pattern on the photoresist. The presence of an additional light absorbing material is necessitated based on the substrate or wafer that is being used and the pattern being defined.

In the subsequent patterning process, a chemically reactive plasma etch is performed, wherein the pre-defined pattern on the photoresist is transferred to the substrate. This process leaves the patterned wafer with the etched photoresist, etch polymer and an anti-reflective coating (ARC) when it is used. A plasma-ash step may be included to aid in the removal of the etched photoresist during the subsequent cleans step(s).

Finally, the remaining of the photoresist layer, etch polymer and the ARC layer (if used) is removed. Chemical solutions, generically called strippers may be used for removing the aforementioned materials to result in a clean patterned wafer for further processing to add the copper interconnects.

Current backend of the production line of 65 nm and 90 nm process nodes utilize expensive wet chemical mixtures with high solvent composition (ranging from 40-60%) to remove resist and sacrificial antireflective (light absorbing) coating (ARC) at via and trench layers of the inter-layer dielectric (ILD) during the dual-damascene structure formation. Some of the cleans solutions include two-step processes that compound the costs and processing time for each dielectric layer in a manufacturing environment. Generally the cleans process is required to remove the desired material without significant damage to the ILD and with high degree of compatibility with exposed metals (like copper and tungsten). It is desired to minimize the solvent usage and reduce impact on waste stream from the backend fabrication cleans processes.

### BRIEF DESCRIPTION OF THE DRAWINGS

In order to better understand the present invention, and appreciate its practical applications, the following Figures are provided and referenced hereafter. It should be noted that the Figures are given as examples only and in no way limit the scope of the invention. Like components are denoted by like reference numerals.

FIG. 1A is a scanning electron microscopy (XSEM) image of etched vias before being subjected to an aqueous solution according to embodiments of the present invention.

FIG. 1B is a XSEM image of etched vias after being subjected to an aqueous solution according to embodiments of the present invention.

FIG. 2A is a XSEM image of trenches in dual damascene patterning scheme before being subjected to an aqueous solution according to embodiments of the present invention.

FIG. 2B is a XSEM image of trenches in dual damascene patterning scheme after being subjected to an aqueous solution according to embodiments of the present invention (possibly without an ash process).

FIG. 3A and FIG. 3B are a XSEM images of dual damascene structures after etch-stop cleans (with aqueous solution according to embodiments of the present invention) showing Cu compatibility.

FIG. 4 showing W compatibility of the solvent-free photoresist cleans aqueous solution according to embodiments of the present invention.

FIG. 5 is a table of normalized critical dimension (CD) comparing vias and trenches that underwent a solvent-free treatment according to embodiments of the present invention with a wafer that underwent common treatment that involves solvents, in a dual damascene structure.

FIG. 6 is a table of normalized defect count at the end of the patterning process, comparing a wafer that underwent a solvent-free treatment according to embodiments of the present invention with a wafer that underwent common treatment that involves solvents, in a dual damascene structure.

FIG. 7 is a table comparing the ratio of various CD of the solventless cleans (according to embodiments of the present invention) to that of solvent-based cleans.

FIG. 8 is a flow chart of a method for removal of photoresist and/or ARC, according to embodiments of the present invention.

### DETAILED DESCRIPTION OF EMBODIMENTS

In the following detailed description, numerous specific details are set forth in order to provide a thorough understanding of the invention. However it will be understood by those of ordinary skill in the art that the present invention may be practiced without these specific details. In other instances, well-known methods, procedures, components and circuits have not been described in detail so as not to obscure the present invention.

According to embodiments of the present invention a cleans process for jointly removing etched photoresist, etch polymer and antireflective coating selective to the dielectric material off an etched wafer is made possible at via and trench layers of patterning, while being copper compatible.

A photoresist stripper according to embodiments of the present invention may have no solvent content.

Wafer fabrication facilities (also known as FABs) which may have preferred infrastructure or equipment to support multi-step clean process can utilize much simpler and less complex chemicals involving shorter recipe times at lower temperatures, according to embodiments of the present invention.

Main elements of the photoresist stripper according to embodiments of the present invention may include aqueous clean formulations which allow single step cleans substantially bringing down chemical costs and environmental foot-print.

Photoresist stripper formulations according to embodiments of the present invention can offer drop-in replacement to existing integration schemes and may be compatible with inter layer dielectrics (ILDs) such as, for example, non-porous or low-porosity (7-14%) carbon doped oxide (CDO) or silicon oxide (SiO2).

Photoresist stripper formulations according to the present invention may offer single step cleans with shorter process time (relatively to processes used to-date), thereby improving module output. Formulations are aqueous, which are more environmentally benign. Lower temperature processes also significantly reduce module/equipment downtime due to shorter temp-up duration.

It may be desirable to avoid plasma ash cleans for removing photoresist and ARC (e.g. sacrificial light absorbing material) in the back-end of line (for, for example, copper interconnects) in the via first integration scheme to minimize both mechanical and electrical damage in the dielectric (to avoid increase in capacitance). Embodiments of the present invention may provide simplification of the chemical mixture for removing etched photoresist, etch polymer and ARC from patterned dielectrics. A photoresist removal process according to embodiments of the present invention may be subjected to constraints, which include:

A) CD (critical dimensions) of via and trench structures achieved on the patterned dielectric after a solvent-free cleans process according to embodiments of the present invention, relative to current solvent-containing solutions.

B) Defects (unremoved residues) achieved on the patterned dielectric after a solvent-free cleans process according to embodiments of the present invention relative to current solvent-containing solutions.

C) Photoresist removal according to embodiments of the present invention may be a “Plug and play” process which may need no changes in the existing or previously developed lithography or plasma etch process.

Details of experimental findings are detailed in this section:

According to embodiments of the present invention, a composition of a photoresist removal solution formulation (by weight percent) is given below:

1-12% TMAH (tetramethylammonium hydroxide) or other organic bases like tetraethylammonium hydroxide or tetrapropylammonium hydroxide or tetrabutylammonium hydroxide or methyltripropylammonium hydroxide or benzyltrimethylammonium hydroxide or choline hydroxide;

0.05-2.5% KOH (potassium hydroxide);

0-0.5% 2-Mercaptobenzimidazole CAS# 583-39-1 (MBI) or 1-Phenyl-1H-tetrazole-5-thiol or 2-MerCaptoBenzoThiazole;

0-12% Hydrogen peroxide; and

Rest—deionized water.

Higher KOH and TMAH concentrations may give lower defects but at the cost of increasing CD's. Further, the cleaning of vias may be aided by using megasonic power at a frequency of about 900 KHz and around 800 W power and operating temperatures were in the range of 40 to 80 degrees Celsius. The mechanical power associated with the wafer spinning and/or spraying of the chemical onto the wafer may enable the via and trench cleans processes to be more efficient (e.g. lower defects with minimal damage to the dielectric).

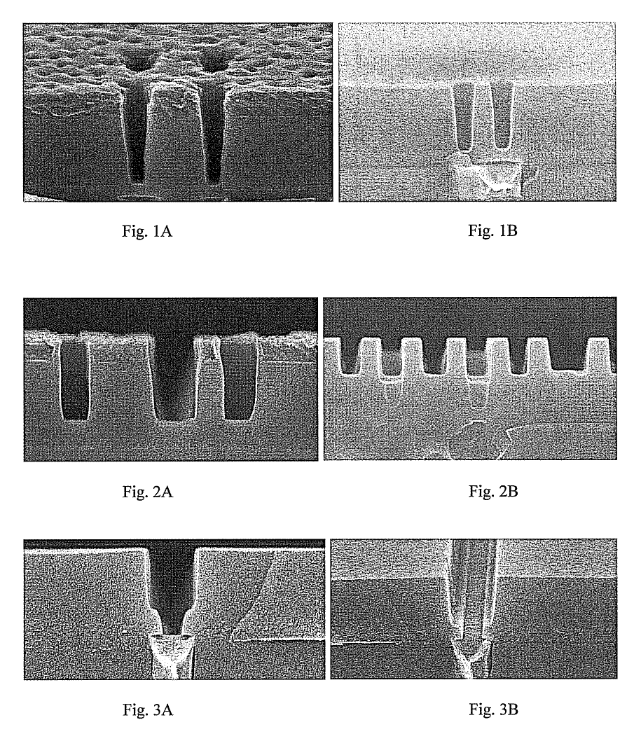

FIG. 1A is a XSEM image of etched vias before being subjected to cleans aqueous solution according to embodiments of the present invention.

FIG. 1B is a XSEM image of etched vias after being subjected to an aqueous solution according to embodiments of the present invention.

FIG. 2A is a XSEM image of trenches in dual damascene patterning scheme before being subjected to an aqueous solution according to embodiments of the present invention.

FIG. 2B is a XSEM image of trenches in dual damascene patterning scheme after being subjected to an aqueous solution according to embodiments of the present invention (possibly without ash process in between).

FIG. 3A and FIG. 3B are a XSEM images of dual damascene structures after etch-stop cleans (with aqueous solution according to embodiments of the present invention) showing Cu compatibility.

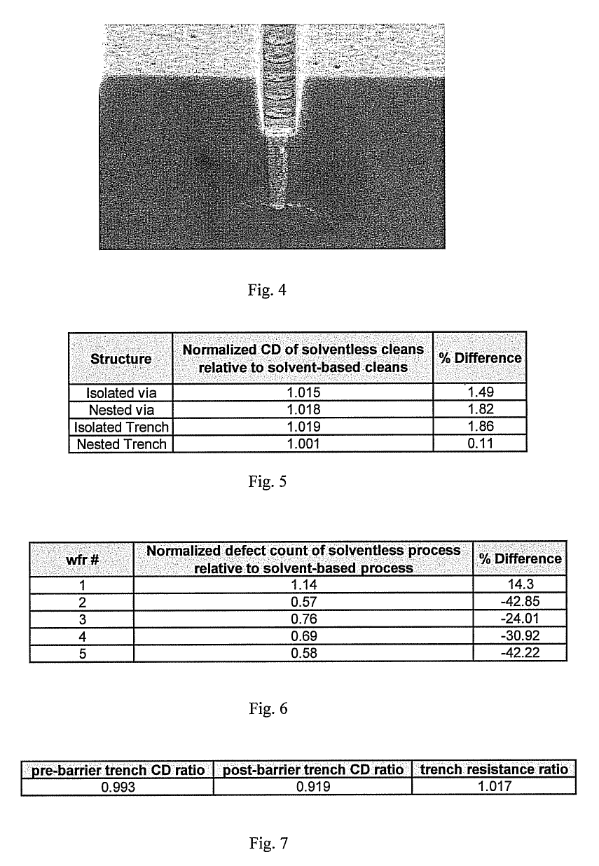

FIG. 4 showing W compatibility of the solvent-free photoresist cleans aqueous solution according to embodiments of the present invention.

It is evident that photoresist, ARC and etch polymer removal using a solution according to embodiments of the present invention was successful in all cases.

FIG. 5 is a table of normalized critical dimension (CD) comparing vias and trenches that underwent a solvent-free treatment according to embodiments of the present invention with a wafer that underwent common treatment that involves solvents, in a dual damascene structure.

FIG. 6 is a table of normalized defect count at the end of the patterning process, comparing a wafer that underwent a solvent-free treatment according to embodiments of the present invention with a wafer that underwent common treatment that involves solvents, in a dual damascene structure.

The tables relates to post-patterning final check critical dimensions (FCCD, FIG. 5) and defects (FIG. 6) on the wafer with a photoresist stripper removal solution according to an embodiment of the present invention (used for all the three cleans types, namely: post via etch, trench etch and etch stop (ES) etch (to expose the underlying Copper), compared with commonly used solution results.

FIG. 7 is a table comparing the ratio of various CD (critical dimensions) of the solventless cleans (presented in this invention) to that of solvent-based cleans. Note the matching trench CD's before barrier deposition and 8% reduction of the trench CD and a concomitant increase in the resistance of the solvent-free process in the copper line, according to embodiments of the preset invention.

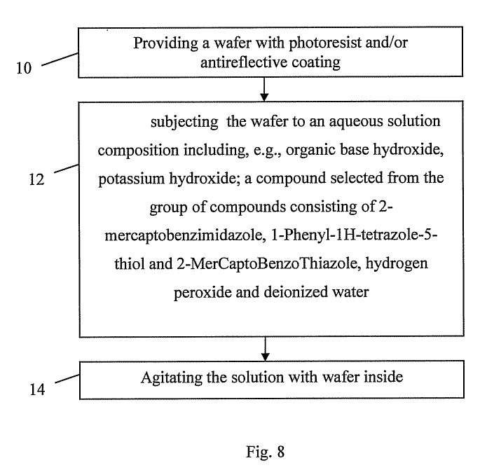

FIG. 8 is a flow chart of a method for removal of photoresist and/or ARC, according to embodiments of the present invention. Referring to FIG. 8, a wafer with photoresist and ARC may be provided (operation 10). The wafer may be subjected to a solution according to embodiments of the present invention (operation 12) and the solution with the wafer inside may be agitated (operation 14). This may result in, for example, removing the photoresist and anti-reflective layer.

Very good performance results for photoresist removal solution according to embodiments of the present invention that may yield desirable photoresist removal results can fall under the following range:

1-12% TMAH (tetramethylammonium hydroxide) or other organic bases like tetraethylammonium hydroxide or tetrapropylammonium hydroxide or tetrabutylammonium hydroxide or methyltripropylammonium hydroxide or benzyltrimethylammonium hydroxide or choline hydroxide;

0.05-2.5% KOH (potassium hydroxide);

0-0.5% 2-Mercaptobenzimidazole CAS# 583-39-1 (MBI) or 1-Phenyl-1H-tetrazole-5-thiol or 2-MerCaptoBenzoThiazole;

0-12% Hydrogen peroxide;

Rest—deionized water.

One embodiment of the present invention includes the following:

Via treatment at a temperature range of 40 to 70 degrees Celsius, treatment duration of 10 to 50 minutes, megasonic energy/agitation at about 900 kHz and 800 W power and/or mechanical agitation associated with wafer spinning and chemical spray.

Trench treatment at a temperature range of 40 to 80 degrees Celsius, duration of 10 to 50 minutes, with above-mentioned agitation conditions.

Etch stop treatment at a temperature range of 40 to 60 degrees Celsius, duration of 3 to 8 minutes.

The above parameter information is given for explanatory purposes relating to the examples discussed hereinabove and in no way limit the scope of the present invention.

Another aspect of solventless (e.g. aqueous) cleans discovered here is that the patterned dielectric is more immune towards the damages caused by the physical vapor deposition-based tantalum barrier deposition process. This is noted by the smaller increase in the CD of the features before and after the deposition of the barrier in the aqueous cleans when compared against that of a solvent-based cleans.

Although it may be desirable to avoid plasma ash cleans for removing photoresist and ARC, a process for the removal of photoresist and ARC involving the use of a solution according to embodiments of the present invention can be also involve a plasma-ash step as well.

While the invention has been described with respect to a limited number of embodiments, it will be appreciated that many variations, modifications and other applications of the invention may be made. Embodiments of the present invention may include other apparatuses for performing the operations herein. The appended claims are intended to cover all such modifications and changes.

What is claimed is:

1. An aqueous solution composition comprising:
a organic base hydroxide;
potassium hydroxide;
a compound selected from the group of compounds consisting of 2-mercaptobenzimidazole, 1-Phenyl-1H-tetrazole-5-thiol and 2-MerCaptoBenzoThiazole;
hydrogen peroxide; and
deionized water.

2. The aqueous solution as claimed in claim 1, wherein the organic base hydroxide is selected from the group of compounds consisting of TMAH (tetramethylammonium hydroxide), tetraethylammonium hydroxide, tetrapropylammonium hydroxide, tetrabutylammonium hydroxide, methyltripropylammonium hydroxide, benzyltrimethylammonium hydroxide and choline hydroxide.

3. The aqueous solution as claimed in claim 1, wherein
the organic base hydroxide comprises between 1% and 12% by weight of the aqueous solution;
the potassium hydroxide comprises between 0.05% and 2.5% by weight of the aqueous solution;
the compound selected from the group of compounds consisting of 2-mercaptobenzimidazole, 1-Phenyl-1H-tetrazole-5-thiol and 2-MerCaptoBenzoThiazole comprises between 0% and 0.5% by weight of the aqueous solution; and
the hydrogen peroxide comprises between 0% and 12% by weight of the aqueous solution.

4. A method comprising:
removing a photoresist and an anti-reflective layer from a wafer using an aqueous solution composition which comprises:
a organic base hydroxide;
potassium hydroxide;
a compound selected from the group of compounds consisting of 2-mercaptobenzimidazole, 1-Phenyl-1H-tetrazole-5-thiol and 2-MerCaptoBenzoThiazole;
hydrogen peroxide; and
deionized water.

5. The method as claimed in claim 4, wherein the organic base hydroxide is selected from the group of compounds consisting of TMAH (tetramethylammonium hydroxide), tetraethylammonium hydroxide, tetrapropylammonium hydroxide, tetrabutylammonium hydroxide, methyltripropylammonium hydroxide, benzyltrimethylammonium hydroxide and choline hydroxide.

6. The method as claimed in claim 4, wherein
the organic base hydroxide comprises between 1% and 12% by weight of the aqueous solution;
the potassium hydroxide comprises between 0.05% and 2.5% by weight of the aqueous solution;
the compound selected from the group of compounds consisting of 2-mercaptobenzimidazole, 1-Phenyl-1H-tetrazole-5-thiol and 2-MerCaptoBenzoThiazole comprises between 0% and 0.5% by weight of the aqueous solution; and
the hydrogen peroxide comprises between 0% and 12% by weight of the aqueous solution.

7. The method as claimed in claim 4, further comprising using megasonic power of around 800 W at a frequency of about 900 KHz.

8. The method as claimed in claim 4, further comprising performing the removal of the photoresist and the anti-reflective layer from the wafer at operating temperatures in the range of 40 to 80 degrees Celsius.

9. The method as claimed in claim 4, comprising performing via treatment at a temperature range of 40 to 70 degrees Celsius, treatment duration of 10 to 50 minutes, agitation at about 900 kHz and about 800 W power.

10. The method as claimed in claim 9, further comprising mechanical agitation with wafer spinning and spraying of the solution.

11. The method as claimed in claim 4, comprising performing trench treatment at a temperature range of 40 to 80 degrees Celsius, duration of 15 to 50 minutes and agitation at about 900 kHz and about 800 W power.

12. The method as claimed in claim 4, wherein the treatment comprises etch stop treatment at a temperature range of 40 to 60 degrees Celsius and duration of 3 to 8 minutes.
